(19) United States
(12) Patent Application Publication
(10) Pub. No.: US 2006/0261036 A1
(43) Pub. Date: Nov. 23, 2006

(54) Method for patterning on a wafer having at least one substrate for the realization of an integrated circuit

(75) Inventors: Giuseppe Fazio, Inzago (IT); Alessandro Spandre, Pavia (IT); Pietro Petruzza, Pessano Con Bornago (IT)

Correspondence Address: SEED INTELLECTUAL PROPERTY LAW GROUP PLLC, 701 FIFTH AVENUE, SUITE 6300, SEATTLE, WA, 98104-7092, US

(73) Assignee: STMicroelectronics S.r.l., Agrate Brianza (IT)

(21) Appl. No.: 11/401,113

(22) Filed: Apr. 10, 2006

(30) Foreign Application Priority Data
Apr. 11, 2005 (EP) 05425206.9

(51) Int. Cl. G01L 21/30; H01L 21/302; C23F 1/00; B44C 1/22

(52) U.S. Cl. 216/59; 438/689; 216/60; 438/706; 216/67

(57) ABSTRACT

A method is provided for patterning a wafer comprising at least one substrate for the manufacture of an integrated circuit. The method comprises: etching at least one portion of the substrate with a reactive gas plasma to obtain an optical emission signal, resulting from the products of the reaction between the plasma and the substrate and having a predetermined spectral fingerprint; carrying on the etching of the substrate up to a predetermined end point; and monitoring the spectral fingerprint of the optical emission signal to detect the etching end point. The method comprises the further insertion of an inert gas in the plasma to obtain an increase in the intensity of the optical emission signal.

### TECHNICAL FIELD

The present disclosure relates in its more general aspect to the manufacture of electronic semiconductor devices, and more particularly but not exclusively to a method for patterning a wafer comprising at least one substrate for the manufacture of an integrated circuit.

In its even more particular but not exclusive aspects, the method comprises:

etching at least one substrate portion with a reactive gas plasma obtaining an optical emission signal resulting from the products of a reaction between the plasma and the substrate and having a predetermined spectral fingerprint,

carrying on the etching of the at least one substrate portion up to a predetermined end point, and

monitoring the spectral fingerprint of the optical emission signal to detect this end point of the etching.

### BACKGROUND INFORMATION

The manufacture of electronic semiconductor devices is performed by exposing silicon wafers to a series of chemical-physical treatments, allowing integrated circuits to be defined on the surface thereof, such as for example a memory cell.

In particular, in order to define submicrometric patterns on a wafer substrate, a widely used process technique is the reactive gas plasma etching (low-pressure ionized gas).

This technique is an anisotropic process allowing the substrate material to be removed by following a preferential direction, in most cases corresponding to the perpendicular direction of the substrate to be etched.

A problem associated to the reactive gas plasma etching method is the difficulty to detect a predetermined end point of the etching step, e.g., the moment when a predetermined amount, or a whole substrate has been removed, thereby obtaining a full substrate etching.

A technique to check the end point of an etching step is the one adopting the optical emission spectroscopy (OES).

The optical emission spectroscopy allows the electromagnetic radiations emitted by species in non-equilibrium conditions produced by the reaction between the plasma and the substrate to be monitored.

In particular, these are radiations emitted by the products of the reaction between the plasma and the substrate, corresponding to electronic transitions of molecular or atomic levels. Being electronic transitions, the radiations being emitted are detected in the range of UV frequencies.

The emission spectrum monitoring is particularly suitable to the aim, since the signal intensity varies during the substrate etching. Generally the signal considerably varies in correspondence with the end point.

Therefore, in order to detect the etching step end point, the spectral fingerprint of the radiations being emitted at a predetermined wavelength in the UV is monitored and the emission band intensity variation is checked.

OES is a technique being per se effective to check the end point of an etching step.

Nevertheless, it is not always possible to detect a typical emission band in correspondence with the end point. In particular, some reactive gas plasmas being presently used do not allow a significant intensity variation of the emission signal to be detected.

As a consequence, in order to obviate this problem, it is necessary to adopt particular practical expedients when this technique is applied.

Some known methods are provided to conveniently vary the reactive gas plasma, e.g., to vary the etching chemistry, during the whole etching step in order to use a different reactive gas plasma between a start point and an end point.

This last method has, however, the drawback to require each time the definition of new etching process parameters both from the morphological point of view and from the electric point of view. It is moreover necessary to provide different etching chemistries according to the substrate to be etched.

Other methods provide the use of more sophisticated hardware devices capable to detect more precisely the emission band intensity variation in correspondence with the end point. This method has, however, the drawback to require the use of more and more sophisticated hardware devices that are not always compatible with the traditional instruments used in the etching process, and requiring anyway a considerable cost increase.

Both known methods have the additional drawback to be ineffective when the etching step provides the etching of a small substrate area with respect to the whole wafer, for example lower than 5%.

In this case, the optical signal being emitted has a further reduced intensity since, because of the reduced etching area, also etching by-products, determining the radiation emission, are proportionally in a relatively reduced number.

This drawback becomes particularly evident when an etching step is performed on a silicon nitride film landing over a silicon oxide substrate by using a plasma containing Cl₂, BCl₃ and CHF₃. This etching process enables obtaining tapered trenches having very small size with respect to the whole wafer.

In such a case, the plasma containing Cl₂, BCl₃ and CHF₃ is not selective between the silicon nitride film and the silicon oxide substrate, namely the plasma containing Cl₂, BCl₃ and CHF₃ indifferently etches both the silicon nitride film and the silicon oxide substrate. Therefore, the small patterning area together with the non-selective etching process of silicon nitride does not allow reliable endpoint detection.

With regard to this etching process, it is also to be noted that the plasma containing Cl₂, BCl₃ and CHF₃ has been set up with the aim of having the peculiar tapered morphology of the trenches defined. Therefore the etching chemistry being particularly suitable for the stated purpose, should not be changed.

### BRIEF SUMMARY OF THE INVENTION

An embodiment of the present invention provides a method for patterning a wafer for the manufacture of integrated circuits, wherein the method allows the end point of an etching process to be checked even in the case of a relatively reduced area etching with respect to the whole wafer area.

According to one embodiment of the invention, the method comprises, a step wherein an inert gas, which is indifferent in the etching step, is added to the reactive gas plasma, and wherein the inert gas, although not being involved in the etching step, is able to affect the optical emission signal.

In such a way, the inert gas does not change the etching chemistry but only serves to enhance the emission intensity with respect to the etching step carried out without inert gas.

According to another embodiment of the invention, a method for patterning a film of silicon nitride landing over a silicon oxide substrate for the manufacture of an integrated circuit is provided. The method comprises:

etching at least one portion of a silicon nitride surface with plasma containing Cl₂, BCl₃ and CHF₃, whereby performing an etching reaction to define tapered trenches within the silicon nitride;

adding an inert gas to the plasma containing Cl₂, BCl₃ and CHF₃ wherein the inert gas is indifferent in the etching reaction;

monitoring an infrared (IR) frequency emission signal resulting from the etching reaction; and

correlating a variation of the infrared frequency emission signal with an etching across an interface area between the silicon nitride and the silicon oxide substrate.

A result of this further embodiment is that from the IR signal it is possible to unequivocally determine the chemical nature of the molecular fragments produced by the reaction of the plasma with the film, e.g., of the etching reaction products, and thus to have useful indications on the reaction.

Therefore, detecting a change of the molecular fragments enables detection of the reaching of the interface. Thanks to the IR detection, the lack of selectivity in the etching process is overcome.

It is to be noted that the IR signal is enhanced, by the addition of inert gas, more than UV signal during the etching step across the silicon nitride/silicon oxide substrate interface.

Accordingly, infrared frequencies are used instead of UV frequencies, notwithstanding the conventional use of electronic emissions for endpoint detection and notwithstanding electronic transitions are higher than vibrational ones.

Moreover, according to this further embodiment, the inert gas addition has a negligible effect upon morphology and dimensions of the trenches, whereby the obtained tapered trenches are very similar to the trenches obtained by a standard process without adding any inert gas.

Further features of the invention will be apparent from the following description of some embodiments thereof given by way of non-limiting example with reference to the drawings.

### BRIEF DESCRIPTION OF THE SEVERAL VIEWS OF THE DRAWINGS

FIGS. 1A-1B are respective schematic views of an operative sequence of the method according to one embodimentof the present invention.

FIG. 2 shows a diagram of the in-time-variation trend of the intensity of an optical emission signal at a predetermined frequency.

FIGS. 3a-3c respectively show further diagrams of the in-time-variation trend of the intensity of an optical emission signal at a predetermined frequency.

FIG. 4a shows an image of a trench obtained by a conventional method without the use of inert gas.

FIG. 4b shows an image of a trench obtained by a method according to an embodiment of the invention.

### DETAILED DESCRIPTION

Embodiments of a method for patterning on a wafer having at least one substrate for the realization of an integrated circuit are described herein. In the following description, numerous specific details are given to provide a thorough understanding of embodiments. One skilled in the relevant art will recognize, however, that the invention can be practiced without one or more of the specific details, or with other methods, components, materials, etc. In other instances, well-known structures, materials, or operations are not shown or described in detail to avoid obscuring aspects of the invention.

Reference throughout this specification to “one embodiment” or “an embodiment” means that a particular feature, structure, or characteristic described in connection with the embodiment is included in at least one embodiment. Thus, the appearances of the phrases “in one embodiment” or “in an embodiment” in various places throughout this specification are not necessarily all referring to the same embodiment. Furthermore, the particular features, structures, or characteristics may be combined in any suitable manner in one or more embodiments.

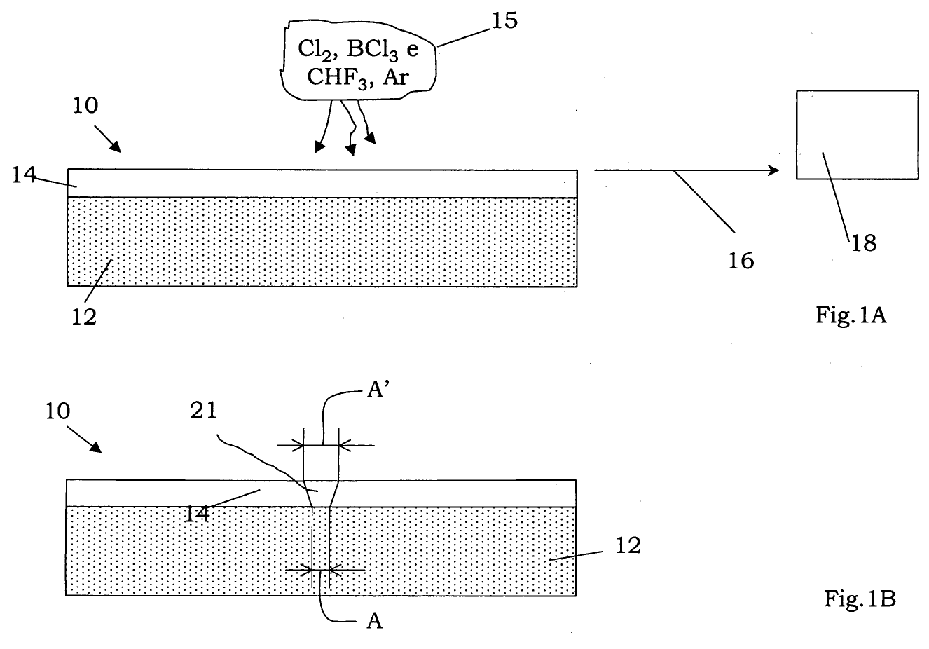

With reference to the figures, and particularly to the example of FIGS. 1 A-1B, a wafer undergoing a sequence of process steps provided by the method according to one embodiment of the present invention is globally and schematically indicated with 10.

The process steps and structures described hereafter do not form a complete process flow for producing integrated circuits. In fact the embodiments according to the present invention can be implemented together with the integrated circuit manufacturing techniques presently used in this field, and only those process steps being commonly used which are necessary to understand the embodiments of the invention are described hereafter.

The figures representing wafer cross sections, during manufacturing, are not drawn to scale, but they are drawn instead to show the features of the embodiments invention.

In the case of the solution being shown, not limiting in the scope of the present invention, the wafer 10 comprises two layers: a first substrate forming a landing substrate 12 and a second substrate 14 positioned above the landing substrate 12.

The landing substrate 12 of an embodiment is made of silicon oxide, while the second substrate 14 is made of silicon nitride, for example. Other embodiments can provide substrates made of other types of materials.

In particular, with reference to FIGS. 1A-1B, the method comprises the following steps schematically indicated hereafter:

etching at least one portion of the substrate 14 with a reactive gas plasma 15 (FIG. 1A) to obtain an optical emission signal, indicated with the number 16, resulting from the products of a reaction between the plasma 15 and the substrate 14 and having a predetermined spectral fingerprint,

carrying on the etching reaction of the at least one portion of the substrate 14 up to a predetermined end point EP, and

monitoring in time the spectral fingerprint of the optical emission signal 16 by using a convenient detection means 18 to detect this end point from the spectral fingerprint.

For convenience of illustration, in accordance with the embodiments of the present invention, spectral fingerprint means the trend of the intensity of an optical emission signal 16 during the etching reaction detected at a predetermined typical wavelength.

In accordance with a furtherfeature of an embodiment of the invention, the method comprises an insertion step wherein an inert gas is added to the etching plasma 15, wherein the inert gas is indifferent in the etching reaction.

The inert gas, although not being involved in the etching reaction, is able to affect the optical emission signal, and in particular to determine an increase in the intensity of the optical emission signal 16, with respect to the optical emission signal that is obtained without adding any inert gas.

In particular, according to an embodiment of the invention, the addition of the inert gas determines an increase in the impacts and collisions and thus an increase in the species in the non-equilibrium condition and this consequently allows the intensity of the optical emission signal 16 to be increased.

In substance, the inert gas serves as a signal enhancer since it is capable to increase the etching evidence by the reactive gas plasma 15.

In particular, during the etching step, the whole spectral fingerprint of the optical signal 16 is increased.

As a consequence, due to the intensity increase, a considerable variation of the optical emission signal 16 is obtained also when a predetermined end point EP is reached and this variation can thus be detected.

An explanation of the phenomenon is made with reference to the following formulas:
A→A⁺+e⁻ (Eq. 1)
(A=Atom of inert gas)
e⁻+B−B→B−B*+e⁻→B B e/o A⁺+B−B→B−B*+A+→B B (Eq. 2)

(B−B=it schematically indicates the substrate undergoing the etching) Plasma emissions 15 result, as above mentioned, from the collision on the substrate 14 of the reactive species (ions and radicals) and electrons deriving from the species used to form plasma.

When an inert gas is added, the electrons and ions resulting from the ionization thereof (Eq. 1) can favor further collisions on the substrate (Eq. 2) and thus increase the spectroscopic emission intensity.

According to another feature of an embodiment of the present invention, the inert gas addition determines a higher increase of the spectral fingerprint for some bands with respect to the others. In particular, a considerable increase is obtained at the infrared frequencies.

For sake of precision, at the same experimental etching conditions, the intensity increase in the IR frequency range, e.g., of the vibrational emissions, is proportionally higher than the UV one, corresponding to electronic transitions.

It is noted that, conventionally with known detection methods, it is not possible to detect a considerable variation of the optical emission signal in the infrared field in correspondence with the end point, since the intensity of a signal IR for vibrational transitions is considerably lower than the intensity of a signal UV.

In this case, however, due to the presence of the inert gas, an increase in the collisions, and thus in the vibrations, between the plasma species is obtained and consequently not only electronic transitions, but also vibrational transitions, and thus the signal intensity in the infrared considerably increase.

In one example embodiment, the detection in the IR is performed in the range between 900 and 950 nm.

The detection in the infrared of the optical emission signal, besides being more effective than the detection in the UV, allows additional information to be obtained with respect to a detection in the UV, e.g., information characterizing the etching process.

In particular, as it is known, the absorption, or detection, IR can be typical for particular molecular fragments. For example an absorption signal IR of the link N—C (nitrogen-carbon) is different if it is an “amino” nitrogen (CH₃NH₂), “amidic” (CH₃CO₂NH₂), etc.

As a consequence, from the absorption signal IR it is possible to unequivocally determine the chemical nature of the molecular fragments produced by the reaction of the plasma 15 on the substrate 14, e.g., of the etching reaction products, and thus to have useful indications on the reaction trend.

It results that the inert gas, besides increasing the optical emission signal 16 in the IR provides new etching process indicators, e.g., it provides information about the nature of the etching reaction products.

In one embodiment of the invention, the method is performed in the following operative modes.

The etching step provides a known etching with a mixture of gases Cl₂, BCl₃ and CHF₃, whereto an inert gas, such as Ar, is added.

For example, in the etching plasma the gases Cl₂, BCl₃, CHF₃ and Ar are in a ratio of 1:1.4:0.1:1 or 1:1.4:0.1:2 respectively.

However, the percentage of Ar in the plasma is comprised in a quite wide range, such as between 10% and 50% in addition to a predetermined amount (100%) of reactive gas in the plasma 15.

In an embodiment, the process is performed by using a known device LAM TCP 9600 PTX. The device is provided with a known emission spectroscopy detector.

In an embodiment, as above mentioned, the etching step with the reactive gas plasma 15 is performed on the second substrate 14, e.g., on the silicon nitride substrate. In this case, the process end point EP corresponds to reaching an interface area between the landing substrate 12 and the second substrate 14, e.g., to the moment when an exposition of the landing substrate 12 occurs.

The interface area being reached, the optical emission signal varies according to a variation of collision by-products, of plasma 15 on the substrate 14.

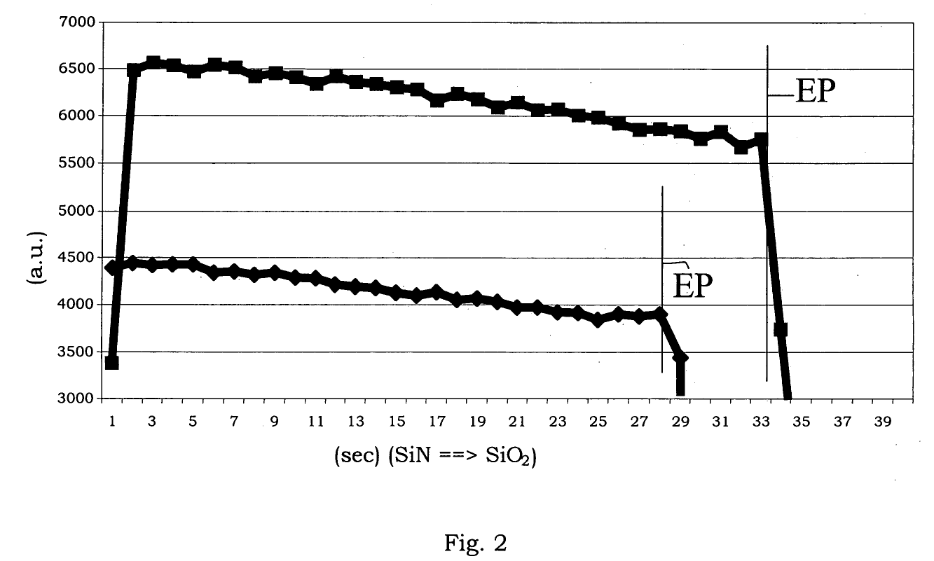

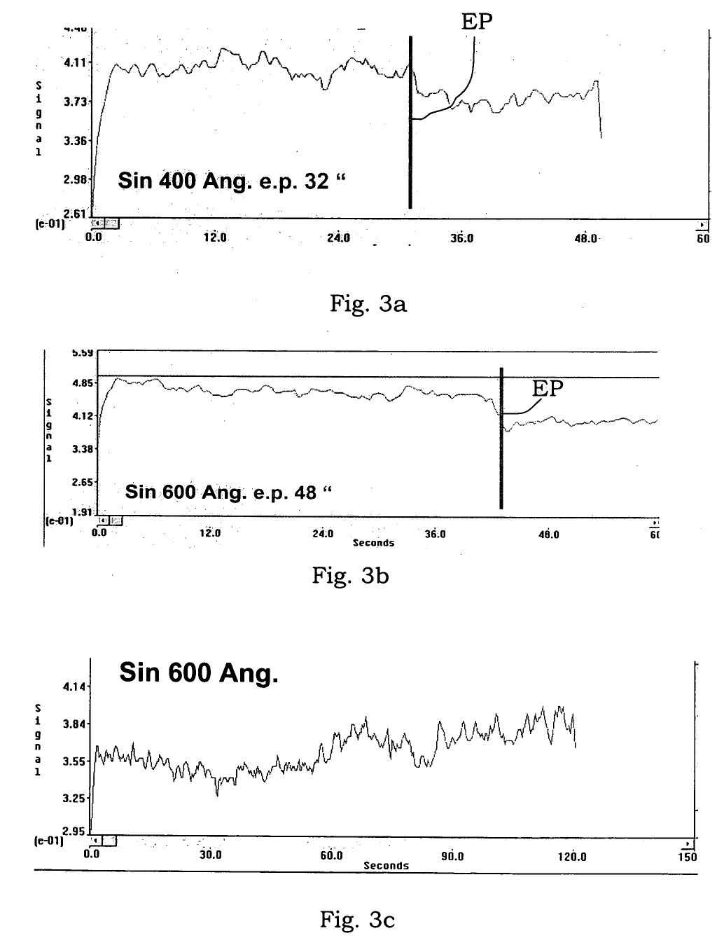

In the specific case, upon reaching the end point a signal decrease occurs (see, e.g., FIGS. 2, 3a-3b).

In the case of the above-described embodiment, the detection of the optical emission signal 16 may be performed at 905 or 906 nm.

Said plasma 15 has an etch-rate on the silicon nitride of about 650 Å/min. In an embodiment, the etching on the second substrate 14 is carried on for very short times (about 40 seconds) up to said end point EP, so to obtain an etching 21 being about 600 Å deep in the silicon nitride.

It is noted, as above mentioned, that the presence of an inert gas does not affect the etching process itself. In fact, the inert gas does not cause a variation of the etching morphology since it is not involved in the etching process.

Moreover, it is pointed out that, actually from the experimental tests performed by the Applicant, it could be noticed that, the inert gas being present, it is possible to obtain an etching 21 having a morphology being substantially identical to an etching 21 performed without inert gas.

The following table collects the results corresponding to an etching speed variation on the substrate 14 after an amount variation of the argon inserted in the plasma 15.

In particular, four tests have been performed.

A first test wherein the plasma 15 is provided with an amount of Ar being inserted corresponding to 15%, a second test wherein the amount of Ar being inserted corresponded to 25% and a third test wherein the amount of Ar being inserted corresponded to 50%.

The results of the three tests have been compared with the result of a base test (Std) wherein the plasma 15 is argon-free.

For completeness of description, it is noted that the additions of Ar are calculated in terms of flow percentages, with respect to the reactive gas flow of the plasma 15 which is intended to be at 100%.

TABLE 1

| | Etching | |
|---|---|---|
| | speed | Unif |
| | (Å/min) | (%) |
| Std | 650 | 11 |
| (*) Std + 10% Ar | 670 | 10 |
| Std + 25% Ar | 690 | 9 |
| Std + 50% Ar | 700 | 12 |

For clarity of description the term Unif(%) indicated in Table 1 means the etching percentage uniformity value on the wafer.

The uniformity is defined by measuring the etching produced by the etching in thirteen different points on the wafer and it is given by the ratio between the difference between the highest value and the lowest value (defined as spread) and twice the average of the 13 values.

The value of Unif(%) is quoted in table 1 to substantially show that the addition of Ar does not vary the etching uniformity on the substrate 14.

According to an embodiment of the invention, due to the inert gas addition, it is possible to obtain an increase of the optical emission signal 16 even when the etching area is relatively reduced.

In fact, according to the above-described principle, see Eq. 1 and Eq. 2, the amount of Ar added to the plasma 15 is sufficient to determine an increase in the collisions, and thus in the intensity of the signal 16, even when the etching area 21 is very small.

In an embodiment, as it can be observed in the drawings, the etching obtained with the process has a downward-tapered shape and it has a width A of about 58 nm in depth and a width A′ of about 153 nm at the level of the wafer 10 surface (FIG. 1 B).

The above-indicated amplitude values are about 5% with respect to the area of the whole wafer 10.

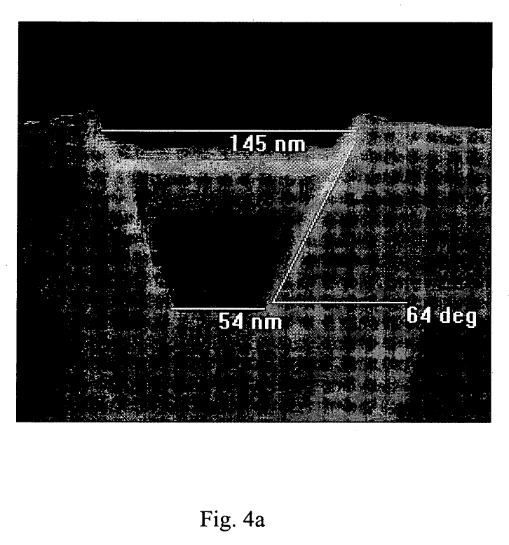

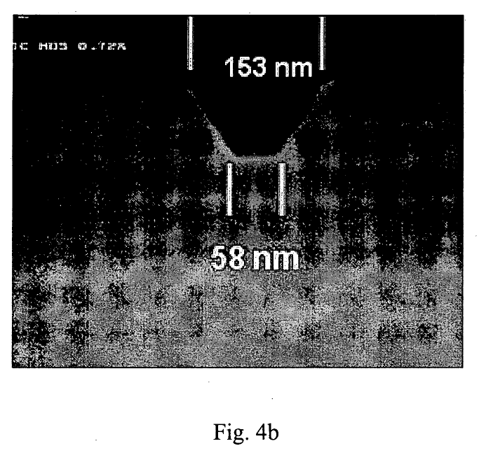

In particular, FIG. 4a shows the morphology of a tapered trench obtained by a standard process without the addition of any inert gas.

FIG. 4b shows a tapered trench obtained by the present embodiment of the invention with the addition of inert gas (Ar). From this comparison, it can be confirmed that the inert gas addition affects neither the profile nor the dimensions of the trench.

It is noted that, in the case of the embodiment being shown, the etching step is not selective per se with respect to the two substrates 12 and 14, e.g., the reactive gas plasma 15 indifferently etches both substrates 12 and 14.

In fact, a metal etching device is used (said LAM TCP9600 PTX) and the reactive gas mixture being used is not selective between the two substrates 12 and 14.

It can thus be observed that, mainly in this case, the detection of the end point EP by using the optical emission spectrum is necessary, otherwise the etching could go on beyond the end point EP, and thus beyond the landing substrate 12 exposure. In substance, without a considerable variation of the signal intensity, a correct etching 21 could not be obtained.

The risk of an overetching, subsequently jeopardizing the device functionality, would in fact be incurred.

As a consequence, due to the method according to the one embodiment, it is possible to determine the end point EP even when the etching is not selective, or it is so to a relatively reduced extent.

This advantage is much more evident in the case of the embodiment being shown, since this reactive gas mixture, although not being selective between the substrates, is particularly suitable to perform the etching being described. For this reason, obviously for the case being described, the reactive gas plasma composition cannot be varied in any way.

In the case of the embodiment being described up to now, the method according to the invention comprises a final step, after having reached the end point, during which a selective over-etching 5:1 (SiN:SiO₂) is performed to clean possible SiN residuals from the bottom of the etching 21.

By way of indication, FIG. 2 shows the trend of the optical emission signal detected at 911 nm up to reach the end point EP respectively without and with inert gas in the plasma 15.

In particular, in the diagram the intensity of the optical emission signal being obtained in indicated in the ordinate, while the plasma etching time on the wafer 10, e.g., on the substrate 14 (SiN) lying on the landing substrate 12 (SiO₂), is indicated in the abscissa.

In order to compare the two optical signals being obtained, the etching has been performed on the same wafer 10 and in substantially identical experimental conditions, obviously except for the composition of the reactive gas plasma 15 being used.

In a first case, an inert-gas-free reactive gas is used (lower signal intensity), while in a second case reactive gas plasma 15 provided with an inert gas is used, in the case being shown Ar (higher signal intensity).

Actually from FIG. 2 it is possible to notice an increase in the variation intensity of the signal 16 during the etching of the interface first substrate 12/second substrate 14.

It is noted that the inert gas insertion allows also the slope of the intensity signal to be increased in correspondence with the end point EP.

In FIGS. 3a-3b it is further possible to observe the detection of an etching process end point EP from the signal trend.

In particular, FIG. 3a relates to an Ar etching process wherein the etching is 40 nm deep and the end point is detected at 32 sec.

FIG. 3b relates to an Ar etching process wherein the etching is 60 nm deep and the end point is detected at 48 sec.

FIG. 3c relates to an etching process without Ar insertion, wherein the etching is 60 nm deep, as in the case of Fgure 3b, and wherein however an end point EP cannot be detected. The optical emission signal being obtained has been recorded beyond 60 sec.

By analyzing FIGS. 3a, 3b, 3 c the following considerations can be drawn.

The first two cases (FIGS. 3a and 3b) emphasize the reproducibility and reliability of the method being used, representing the idea of an embodiment of the invention being provided.

By adding the “enhancer” inert gas, independently from the thickness of the second layer 14 of SiN to be etched, the time corresponding to the etching end point EP is proportionally reached.

In fact, it is noted that, by increasing the etching depth from 40 nm (FIG. 3a) to an etching of 60 nm (FIG. 3b), the time used proportionally increases by about 3/2 of the initial value.

In substance, the highest is the depth of the obtained etching, the highest is the time required, which can be monitored, to reach the end point EP.

From the comparison between FIGS. 3b and 3c, it is also possible to emphasize once more the difference between the optical emission signal obtained in case of plasma provided with inert gas, or in case of inert-gas-free plasma.

One advantage of the above-described method is of providing a fast-implementation method to detect the end point of an etching process even when the etching area is relatively limited.

The method also offers a high application variability and versatility.

In fact, according to the kind of wafer to be etched and to the reactive gases of the plasma 15 to be used, it is possible to choose an inert gas allowing the most considerable increase of the optical emission signal 16.

To this purpose it is noted that the method allows the process chemistry chosen according to the kind of etching to be performed to be kept unchanged.

In fact, the inert gas insertion irrelevantly affects the process chemistry and thus the inert gas can be inserted in any reactive gas plasma with no need to vary the latter.

Moreover, the method can be applied in an etching process which is not selective towards the two substrates forming the wafer, e.g., it indifferently etches either of the substrates.

A further advantage is that, in order to increase the signal, it is not necessary to use sophisticated computerized means.

A further advantage is the possibility to detect the optical emission signal in the IR and to receive further indicative information about the etching process.

All of the above U.S. patents, U.S. patent application publications, U.S. patent applications, foreign patents, foreign patent applications and non-patent publications referred to in this specification and/or listed in the Application Data Sheet, are incorporated herein by reference, in their entirety.

The above description of illustrated embodiments, including what is described in the Abstract, is not intended to be exhaustive or to limit the invention to the precise forms disclosed. While specific embodiments and examples are described herein for illustrative purposes, various equivalent modifications are possible within the scope of the invention and can be made without deviating from the spirit and scope of the invention.

These and other modifications can be made to the invention in light of the above detailed description. The terms used in the following claims should not be construed to limit the invention to the specific embodiments disclosed in the specification and the claims. Rather, the scope of the invention is to be determined entirely by the following claims, which are to be construed in accordance with established doctrines of claim interpretation.

What is claimed is:

1. A method for patterning a wafer having at least one substrate to manufacture an integrated circuit, the method comprising:
etching at least one portion of the substrate with a reactive gas plasma to obtain an optical emission signal resulting from products of a reaction between the plasma and the substrate and having a spectral fingerprint;
carrying on the etching of the portion of the substrate up to an end point;
monitoring the spectral fingerprint of the optical emission signal to detect the end point of the etching; and
before performing the etching, adding an inert gas to the reactive gas plasma, the inert gas being indifferent in the etching reaction and being able to affect the optical emission signal.

2. The method of claim 1 wherein the optical emission signal is detected in an infrared frequency range.

3. The method of claim 1 wherein the optical emission signal is detected between 900 and 950 nm.

4. The method of claim 1 wherein the optical emission signal is detected at 905 nm.

5. The method of claim 1 wherein the optical emission signal is detected at 906 nm.

6. The method of claim 1 wherein the wafer comprises a landing substrate whereon said substrate lies and wherein the end point corresponds to reaching an interface area between the substrate and the landing substrate.

7. The method of claim 6 wherein the substrate is made of silicon nitride.

8. The method of claim 6 wherein the landing substrate is made of silicon.

9. The method of claim 1 wherein the inert gas being added to the plasma is argon.

10. The method of claim 9 wherein the argon is 10% to 50% with respect to whole of the plasma.

11. The method of claim 9, wherein the reactive gas plasma is comprised of a mixture of gases Cl₂, BCl₃ and CHF₃.

12. A method for patterning a film of silicon nitride landing over a silicon oxide substrate to manufacture an integrated circuit, the method comprising:
etching at least one portion of a silicon nitride surface with plasma containing Cl₂, BCl₃ and CHF₃, so as to perform an etching reaction to define tapered trenches within the silicon nitride;
adding an inert gas to the plasma containing Cl₂, BCl₃ and CHF₃ wherein the inert gas is indifferent in the etching reaction
monitoring an infrared frequency emission signal resulting from etching reaction products; and
correlating a variation of the infrared frequency emission signal with an etching across an interface area between the silicon nitride and the silicon oxide substrate.

13. The method of claim 12 wherein the inert gas is argon.

14. The method of claim 13 wherein argon is 10% to 50% with respect to whole of the plasma.

15. The method of claim 14, further comprising, after having reached the interface, performing a selective overetching to clean silicon nitride residuals in the trenches.

16. The method of claim 14 wherein the tapered trenches occupy about 5% with respect to an area of the silicon nitride surface.

17. The method of claim 16 wherein each of the tapered trenches has a depth comprised between 40 nm and 60 nm.

18. The method of claim 17 wherein each of the tapered trenches has a width which is of about 58 nm at a level of the interface area between the silicon nitride and the silicon oxide substrate and of 153 nm at a level of the silicon nitride surface.

19. A method for patterning a wafer having at least one substrate to manufacture an integrated circuit, the method comprising:
adding an inert gas to a reactive gas plasma;
etching at least a portion of the substrate with the reactive gas plasma having the inert gas added thereto;
detecting an optical emission signal resulting from a reaction between the plasma and the substrate, the optical emission signal having a property;
continuing the etching of the portion of the substrate up to an end point; and
monitoring the property of the optical emission signal to detect the end point, wherein the inert gas is not involved in the reaction and is able to affect the optical emission signal.

20. The method of claim 19 wherein adding the inert gas to the plasma includes adding argon gas to the plasma.

21. The method of claim 19 wherein monitoring the property of the optical emission signal includes monitoring an intensity of the optical emission signal.

22. The method of claim 19 wherein etching the portion of the substrate includes etching a silicon nitride substrate to define tapered trenches.

23. The method of claim 22 wherein the end point is associated with reaching another substrate, underlying the silicon nitride substrate, with the etching.

24. The method of claim 23 wherein reaching the another substrate with the etching includes reaching a silicon oxide substrate with the etching.

25. The method of claim 19 wherein detecting the optical emission signal includes detecting the optical emission signal in an infrared range.

26. The method of claim 19 wherein adding the inert gas to the reactive gas plasma includes adding the inert gas to a Cl₂, BCl₃ and CHF₃ gas mixture.
